(19) United States
(12) Patent Application Publication
(10) Pub. No.: US 2026/0282339 A1
(43) Pub. Date: Sep. 17, 2026

(54) SEMICONDUCTOR DEVICE WITH AIR GAP AND SUPPORT PATTERN AND METHOD OF FORMING THE SAME

(71) Applicant: Samsung Electronics Co., Ltd., Suwon-si (KR)

(72) Inventors: Hyunjin Lee, Suwon-si (KR); Yong Kwan Kim, Suwon-si (KR); Hui-Jung Kim, Suwon-si (KR)

(21) Appl. No.: 19/376,248

(22) Filed: Oct. 31, 2025

(30) Foreign Application Priority Data
Mar. 13, 2025 (KR) 10-2025-0032686

(51) Int. Cl. H10B 12/00

(52) U.S. Cl. CPC H10B 12/485; H10B 12/0335; H10B 12/315

(57) ABSTRACT

A semiconductor device includes a bit line extending in a first direction, a word line extending in a second direction intersecting the first direction, a plurality of semiconductor patterns on the bit line and extending in a third direction orthogonal to the first direction and the second direction and spaced apart from each other, a plurality of connection structures respectively disposed on corresponding semiconductor patterns among the plurality of semiconductor patterns, a support pattern between the connection structures, and an air gap below the support pattern. Each of the connection structures comprises a storage node contact and a protection pattern in contact with a sidewall of the storage node contact. A level of a bottom surface of the protection pattern is higher than a level of a bottommost surface of the storage node contact.

### CROSS-REFERENCE TO RELATED APPLICATION

This U.S. nonprovisional application claims priority under 35 U.S.C § 119 to Korean Patent Application No. 10-2025-0032686 filed on Mar. 13, 2025 in the Korean Intellectual Property Office, the disclosure of which is hereby incorporated by reference in its entirety.

### BACKGROUND

Semiconductor devices are important devices in the electronics industry due to their characteristics such as miniaturization, multi-functionalization, and/or low manufacturing cost. Semiconductor devices may be divided into a semiconductor memory device that stores logic data, a semiconductor logic device that processes logic data, and a hybrid semiconductor device that includes a memory element and a logic element, and the like.

In recent years, with the increase in speed and the decrease in power consumption of electronic devices, a semiconductor device incorporated in an electronic device may need to operate at higher speeds and/or lower voltages. In order to satisfy these characteristics, semiconductor devices may become more highly integrated.

### SUMMARY

A semiconductor device according to an example implementation of the present disclosure may comprise: a bit line extending in a first direction; a word line extending in a second direction intersecting the first direction; and a plurality of semiconductor patterns on the bit line and extending in a third direction orthogonal to the first direction and the second direction and spaced apart from each other; a plurality of connection structures respectively disposed on corresponding semiconductor patterns among the plurality of semiconductor patterns; a support pattern between the connection structures; and an air gap below the support pattern, each of the connection structures comprising: a storage node contact; and a protection pattern in contact with at least a portion of a sidewall of the storage node contact, wherein a level of a bottom surface of the protection pattern may be higher than a level of a bottommost surface of the storage node contact.

A semiconductor device according to an example implementation of the present disclosure may comprise: a bit line extending in a first direction; a word line extending in a second direction intersecting the first direction; and a plurality of semiconductor patterns on the bit line and extending in a third direction orthogonal to the first direction and the second direction and spaced apart from each other; a plurality of connection structures respectively disposed on corresponding semiconductor patterns among the plurality of semiconductor patterns; a support pattern between the connection structures; and an air gap below the support pattern, wherein each of the connection structures comprises: a storage node contact, a landing pad above the storage node contact, and a protection pattern in contact with a side wall of the landing pad and a side wall of the storage node contact; wherein the storage node contact may include a first contact side wall exposed to the air gap, a contact bottom surface in contact with a corresponding semiconductor pattern of the plurality of semiconductor patterns, and a contact curved surface between the contact bottom surface and the first contact side wall, wherein the contact curved surface may include a curved surface.

A semiconductor device according to an example implementation of the present disclosure may comprise: a substrate; a bit line extending on the substrate in a first direction parallel to a top surface of the substrate; a word line extending in a second direction intersecting the first direction, the word line including a gate electrode extending along a third direction orthogonal to the first direction and the second direction, and a lower gate capping pattern below a bottom surface of the gate electrode; a plurality of semiconductor patterns over the bit line and extending in the third direction and spaced apart from each other; a plurality of connection structures respectively disposed on corresponding semiconductor patterns among the plurality of semiconductor patterns; data storage patterns on the connection structures; a support pattern between the connection structures; and an air gap below the support pattern, wherein each of the connection structures comprises: a storage node contact, a landing pad above the storage node contact; a protection pattern in contact with a sidewall of the landing pad and a sidewall of a storage node contact, wherein a level of a bottom surface of the protection pattern may be higher than a level of a bottom surface of the storage node contact.

### BRIEF DESCRIPTION OF DRAWINGS

FIG. 1 is a block diagram illustrating a semiconductor device according to some implementations of the present disclosure.

FIGS. 2 and 3 are perspective views schematically illustrating a semiconductor device according to some implementations of the present disclosure, respectively.

FIG. 4 is a layout diagram of a semiconductor device according to some implementations of the present disclosure.

FIGS. 5A to 5C are enlarged views corresponding to P1 in FIG. 4.

FIGS. 6A to 6C are cross-sectional views corresponding to lines A-A′, B-B′, and C-C′ of FIG. 4, respectively.

FIG. 6D is an enlarged view corresponding to P in FIG. 6A.

FIGS. 7A and 7B are cross-sectional views corresponding to lines A-A′ and B-B′ of FIG. 4, respectively, according to an implementation of the present disclosure.

FIG. 7C is an enlarged view corresponding to P of FIG. 7A according to some implementations of the present disclosure.

FIG. 7D is an enlarged view corresponding to P of FIG. 7A according to some implementations of the present disclosure.

FIGS. 8, 9A, 9B, 10, 11A, 11B, 12A, 12B, 13, 14A, 14B, 15A, 15B, 16A, 16B, 17A, and 17B are drawings illustrating a method of manufacturing a semiconductor device according to some implementations of the present disclosure.

### DETAILED DESCRIPTION

Hereinafter, implementations according to present disclosure will be described in more detail with reference to the accompanying drawings.

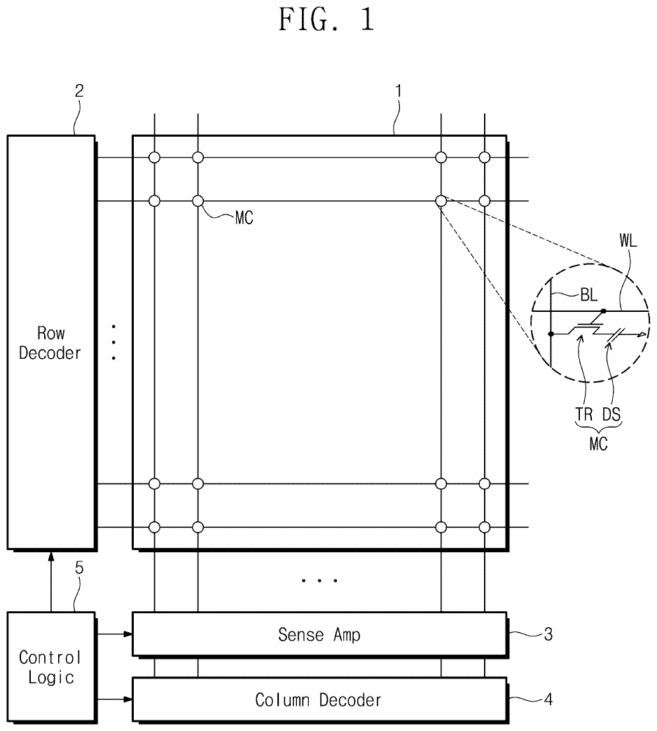

FIG. 1 is a block diagram illustrating a semiconductor device according to some implementations of the present disclosure.

Referring to FIG. 1, a semiconductor device may include a memory cell array 1, a row decoder 2, a sense amplifier 3, a column decoder 4, and a control logic 5.

The memory cell array 1 may include a plurality of memory cells MC arranged two-dimensionally or three-dimensionally. Each of the memory cells MC may be connected between a word line WL and a bit line BL that cross each other. Each of the memory cells MC may include a selection element TR and a data storage element DS. The selection element TR and the data storage element DS may be electrically connected to each other. The selection element TR may be connected to both the word line WL and the bit line BL. In other words, the selection element TR may be provided at a point where the word line WL and the bit line BL crossing each other.

The selection element TR may include a field-effect transistor. The data storage element DS may include a capacitor, a magnetic tunnel junction pattern, or a variable resistor. For example, a gate terminal of the transistor that is the selection element TR may be connected to the word line WL, and source/drain terminals of the transistor may be connected to the bit line BL and the data storage element DS, respectively.

The row decoder 2 may decode an externally input address and select any one of the word lines WL of the memory cell array 1. The address decoded in the row decoder 2 may be provided to a row driver (not shown), and the row driver may provide a voltage to the selected word line WL and the unselected word lines WL, respectively, in response to control of the control circuits.

The sense amplifier 3 may sense, amplify, and output a voltage difference between a selected bit line BL and a reference bit line according to the address decoded from the column decoder 4.

The column decoder 4 may provide a data transfer path between the sense amplifier 3 and an external element (e.g., a memory controller). The column decoder 4 may decode an externally input address to select any one of the bit lines BL. The control logic 5 may generate a control signal that controls an operation of writing or reading data into the memory cell array 1.

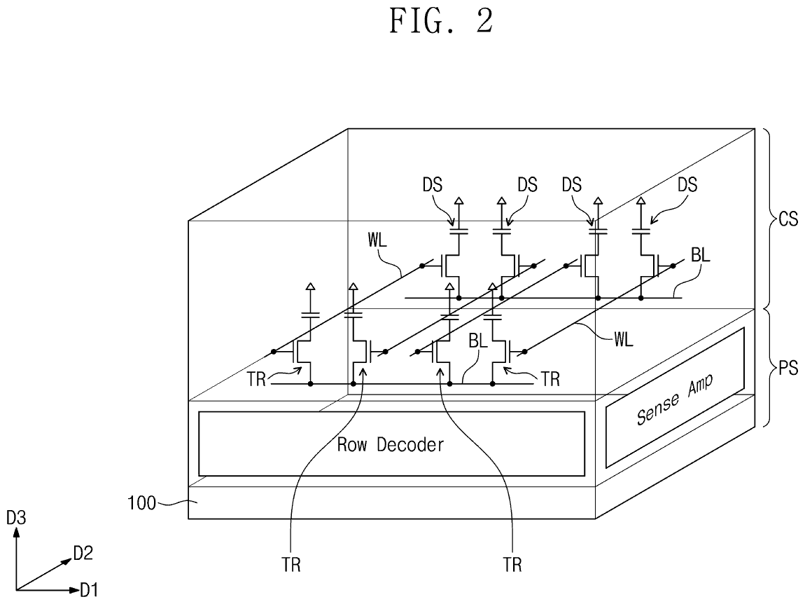

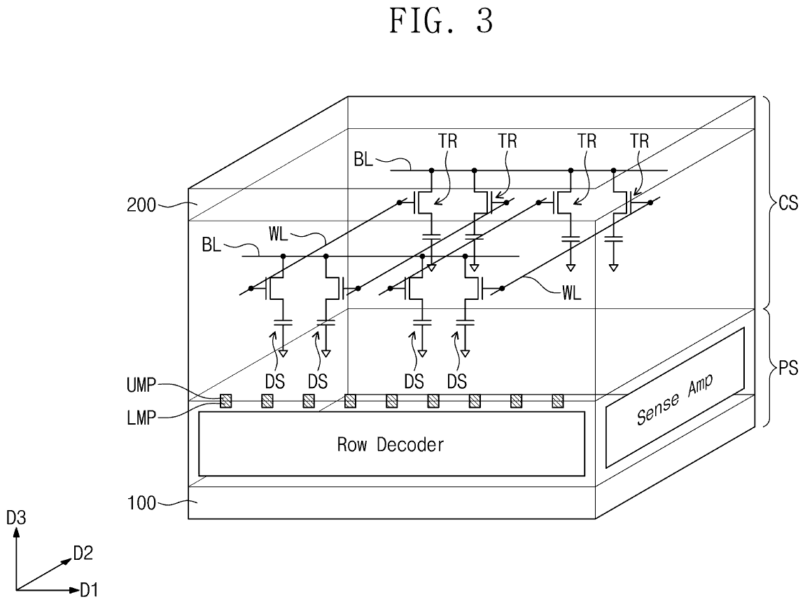

FIGS. 2 and 3 are perspective views schematically illustrating a semiconductor device according to some implementations of the present disclosure, respectively.

Referring to FIGS. 2 and 3, a semiconductor device may include a peripheral circuit structure PS on a substrate 100 and a cell array structure CS connected to the peripheral circuit structure PS. The substrate 100 may have a plate shape extending along a plane defined by a first direction D1 and a second direction D2. The first direction D1 and the second direction D2 are respectively parallel to a top surface of the substrate 100 and may intersect with each other. A third direction D3 may be perpendicular to the top surface of the substrate 100 and may intersect the first direction D1 and the second direction D2.

The peripheral circuit structure PS may include core and peripheral circuits formed on the substrate 100. The core and peripheral circuits may include the row and column decoders 2, 4, the sense amplifier 3, and the control logics 5 described with reference to FIG. 1.

The cell array structure CS may include the memory cell array 1 that includes two-dimensionally or three-dimensionally arranged memory cells MC of FIG. 1. As an example, the selection element TR of each of the memory cells MC of FIG. 1 may include a vertical channel transistor. The vertical channel transistor may include a channel whose lengthwise direction is the third direction D3.

Referring to FIG. 2, the peripheral circuit structure PS may be provided on the substrate 100. The cell array structure CS may be provided on the peripheral circuit structure PS. The peripheral circuit structure PS may be connected to the cell array structure CS through a separate contact.

Referring to FIG. 3, a semiconductor device may have a chip-to-chip (C2C) structure. The peripheral circuit structure PS may be provided on the substrate 100. First metal pads LMP may be provided on an upper portion of the peripheral circuit structure PS. The first metal pads LMP may be electrically connected to the core and peripheral circuits. The first metal pads LMP in the peripheral circuit structure PS may be bonded to second metal pads UMP of the cell array structure CS to be described later. Accordingly, the peripheral circuit structure PS and the cell array structure CS may be bonded.

The cell array structure CS may include a second substrate 200. The second metal pads UMP may be provided on a lower portion of the cell array structure CS. The second metal pads UMP may be electrically connected to the memory cell array 1 (FIG. 1).

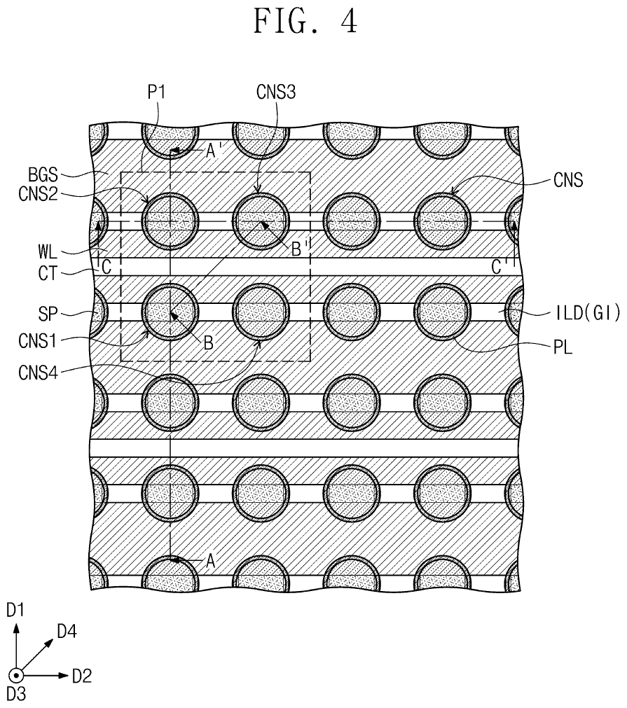

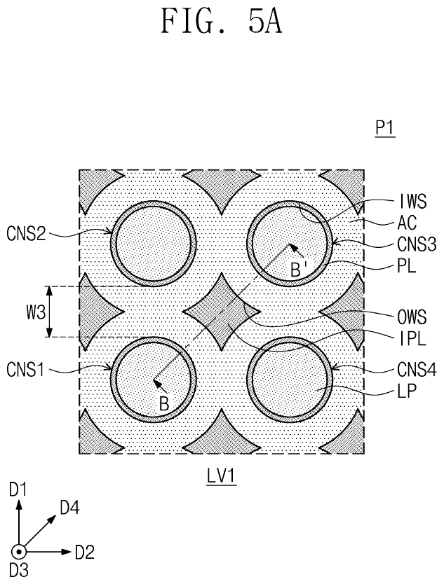

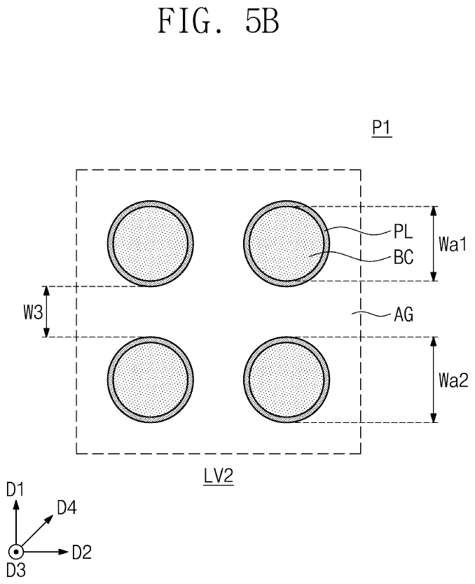

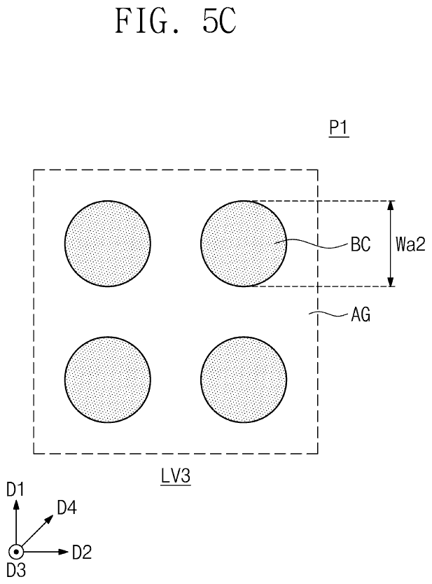

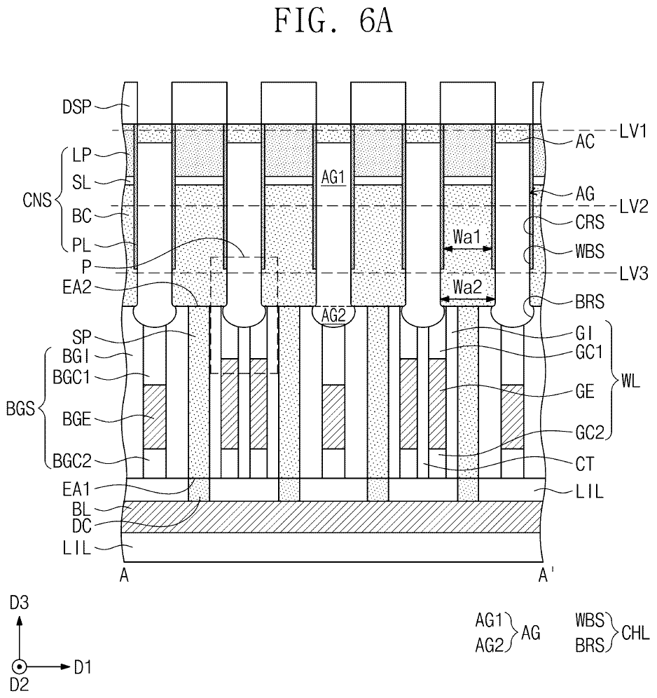

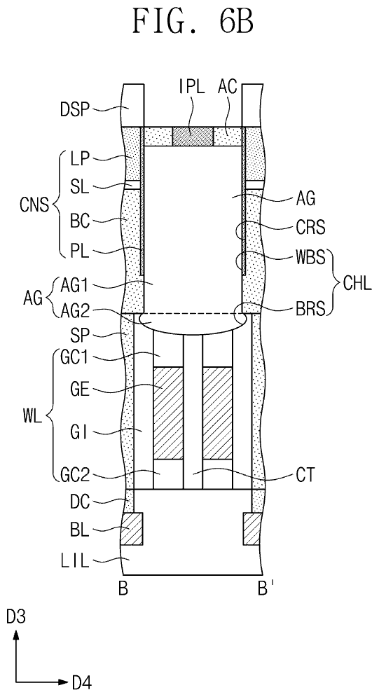

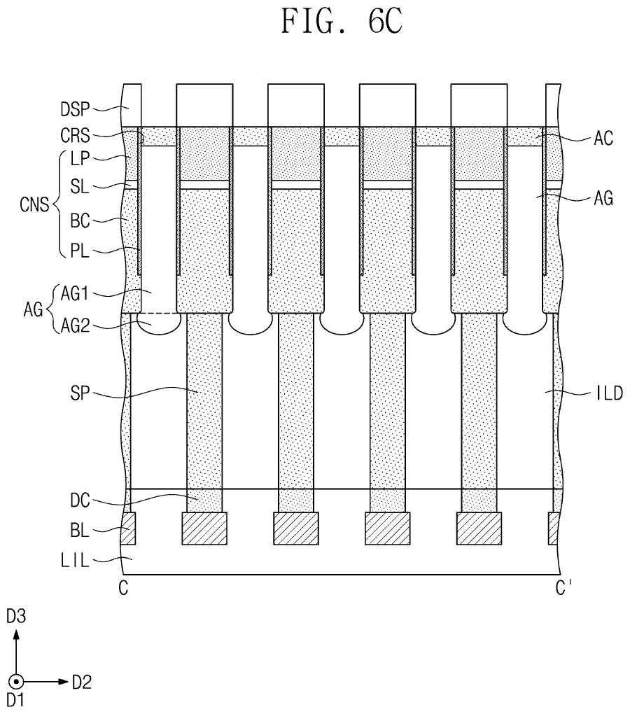

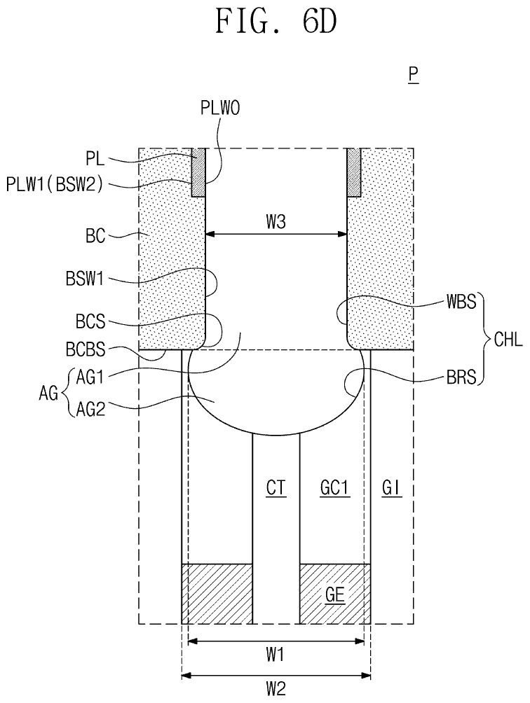

FIG. 4 is a layout diagram illustrating main configurations of a semiconductor device according to some implementations of the present disclosure. FIGS. 5A to 5C are enlarged views corresponding to P1 in FIG. 4. FIGS. 6A-6C are cross-sectional views corresponding to lines A-A′, B-B′, and C-C′ of FIG. 4, respectively. FIG. 6D is an enlarged view corresponding to P in FIG. 6A. FIG. 5A is a plan view at LV1 of FIG. 6A. FIG. 5B is a plan view at LV2 of FIG. 6B. FIG. 5C is a plan view at LV3 of FIG. 6C.

Referring to FIGS. 4, 5A-5C, and 6A-6D, structures within the cell array structure CS described with reference to FIGS. 2 and 3 are shown in more detail.

The semiconductor device may include a lower insulating film LIL. The lower insulating film LIL may include an insulating material. As an example, the lower insulating film LIL may be provided on the lower portion of the cell array structure CS described with reference to FIG. 2. In this case, the lower insulating film LIL may be adjacent to and in contact with the peripheral circuit structure PS described with reference to FIG. 2. In some implementations, the peripheral circuit structure PS described with reference to FIG. 2 may be interposed between the substrate 100 described with reference to FIG. 2 and the lower insulating film LIL. In some implementations, the lower insulating film LIL may include wirings connected to the core and peripheral circuits of the peripheral circuit structure PS described with reference to FIG. 2.

As another example, by flipping the cell array structure (CS in FIG. 2) of the semiconductor device, the lower insulating film LIL may be provided on the cell array structure CS described with reference to FIG. 3. In this case, the lower insulating film LIL may be adjacent to and in contact with the second substrate 200 described with reference to FIG. 3. In the drawings, a plan view and a cross-sectional view of the cell array structure (CS in FIG. 2) of the semiconductor device in an un-inverted state are shown, and the semiconductor device will be described with reference to these drawings, but the present disclosure are not limited thereto.

A bit line BL may be provided in the lower insulating film LIL. The bit line BL may be disposed adjacent to a first edge portion EA1 of a semiconductor pattern SP to be described later. The bit line BL may extend along the first direction D1 in the lower insulating film LIL. The bit line BL may include a conductive material. As an example, the bit line BL may include at least one of a doped semiconductor material (e.g., doped silicon, doped germanium, or the like), a metal material (e. g., Ti, Mo, W, Cu, Al, Ta, Ru, Ir, Co, or the like), a metal silicide (e. g, a silicide of Ti, Mo, W, Cu, A1, Ta, Ru, Ir, Co, or the like) or a metal nitride (e.g., a nitride of Ti, Mo, W, Cu, Al, Ta, Ru, Ir, Co, or the like). The bit line BL may be a single film or a composite film. A plurality of the bit lines BL may be provided. The bit lines BL may be spaced apart from each other in the second direction D2 intersecting the first direction D1.

A bit line contact DC may be provided in the lower insulating film LIL. The bit line contact DC may be provided on the bit line BL. The bit line contact DC may be interposed between the bit line BL and the first edge portion EA1 of the semiconductor pattern SP to be described later. The bit line BL may be connected to the semiconductor pattern SP through the bit line contact DC. The bit line contact DC may include a conductive material. In one example, the bit line contact DC may include doped silicon. A plurality of the bit line contacts DC may be provided. The bit line contacts DC may be spaced apart from each other in the first direction D1 on a single bit line BL. In some other implementations, the bit line contact DC may be omitted. In this case, the bit line BL may be in contact with the semiconductor pattern SP, and the first edge portion EA1 of the semiconductor pattern SP may include a region doped with impurities.

The semiconductor pattern SP may be provided over the bit line BL. As an example, the semiconductor pattern SP may be provided on a top surface of the bit line contact DC. The semiconductor pattern SP may extend on the bit line BL along the third direction D3 orthogonal to the first direction D1 and the second direction D2. A plurality of the semiconductor patterns SP may be provided. The semiconductor patterns SP may be spaced apart from each other in the first direction D1 on a single bit line BL. The semiconductor patterns SP may be spaced apart from each other in the second direction D2.

The semiconductor pattern SP may include a semiconductor material. As an example, the semiconductor pattern SP may include at least one of silicon (e.g., single crystal silicon), germanium, or silicon-germanium. For example, the semiconductor pattern SP may include oxide semiconductor materials. In this case, the oxide semiconductor materials may include, but are not limited to, at least one of InGaZnO, InGaSiO, InSnZnO, InZnO, ZnO, ZnSnO, ZnON, ZrZnSnO, SnO, HfInZnO, GaZnSnO, AlZnSnO, YbGaZnO, or InGaO. As an example, the semiconductor pattern SP may include Indium Gallium Zinc Oxide (IGZO). As an example, the semiconductor pattern SP may include two-dimensional semiconductor materials. In this case, the two-dimensional semiconductor materials may include graphene, carbon nanotubes, or a combination thereof.

A word line WL may be provided on a side of the semiconductor pattern SP. The word line WL may be interposed between the semiconductor patterns SP adjacent to each other in the first direction D1. The word line WL may extend along the second direction D2. A plurality of the word lines WL may be provided. The word lines WL may be spaced apart from each other in the first direction D1. As an example, a pair of the word lines WL adjacent to each other in the first direction D1 may be interposed between the semiconductor patterns SP adjacent to each other in the first direction D1. As an example, a pair of the word lines WL adjacent to each other in the first direction D1 may be spaced apart from each other with a cutting pattern CT to be described later interposed therebetween.

The word line WL may include a gate electrode GE extending along the second direction D2 and the third direction D3, a gate insulating pattern GI between the semiconductor pattern SP and the gate electrode GE, an upper gate capping pattern GC1 on an upper surface of the gate electrode GE, and a lower gate capping pattern GC2 on a bottom surface of the gate electrodes GE. The gate electrode GE may include conductive materials. As an example, the gate electrode GE may include at least one of a metal material (for example, Ti, Mo, W, Cu, Al, Ta, Ru, Ir, Co, or the like), a metal silicide (for example, a silicide of Ti, Mo, W, Cu, A1, Ta, Ru, Ir, Co or the like), or a metal nitride (for example, nitride of Ti, Mo, W, Cu, Al, Ta, Ir, or the like). In an example, the gate insulating pattern GI may include at least one of silicon oxide or a high dielectric material. As used herein, a high dielectric material may be defined as a material having a dielectric constant higher than that of silicon oxide. Each of the upper gate capping pattern GC1 and the lower gate capping pattern GC2 may include an insulating material. The upper gate capping pattern GC1 and the lower gate capping pattern GC2 may include, for example, an oxide.

The cutting pattern CT may be interposed between word lines WL adjacent to each other in the first direction D1. The cutting pattern CT may extend along the third direction D3. As an example, the cutting pattern CT may include an insulating material.

A back gate structure BGS may be provided on a side surface of the semiconductor pattern SP. The back gate structure BGS may be interposed between the semiconductor patterns SP adjacent to each other in the first direction D1. The back gate structure BGS and the word line WL may be spaced apart from each other in the first direction D1 with the semiconductor pattern SP interposed therebetween. The back gate structure BGS may extend along the second direction D2 between the semiconductor patterns SP adjacent to each other in the first direction D1. A plurality of the back gate structures BGS may be provided. The back gate structures BGS may be spaced apart from each other in the first direction D1.

When the back gate structure BGS is provided, a threshold voltage of the transistor including the semiconductor pattern SP may be adjusted by a voltage applied to the back gate structure BGS. Adjusting the threshold voltage by the back gate structure BGS may be easier than adjusting the threshold voltage by injecting impurities into the semiconductor pattern SP. By adjusting the threshold voltage by the back gate structure BGS, the transistor may be prevented from being unnecessarily turned on.

The back gate structure BGS may include a back gate electrode BGE, a first back gate capping pattern BGC1 on a top surface of the back gate electrode BGE, a second back gate capping patterns BGC2 on a bottom surface of the back gate electrode BGE, and a back gate insulating pattern BGI. The back gate insulating pattern BGI may cover side surfaces of the back gate electrode BGE, the first back gate capping pattern BGC1, and the second back gate capping patterns BGC2. As an example, the back gate electrode BGE may include at least one of a metal material (e.g., Ti, Mo, W, Cu, Al, Ta, Ru, Ir, Co, or the like), a metal silicide (e.g., a silicide of Ti, Mo, W, Cu, Al, Ta, Ru, Ir, Co, or the like), or a metal nitride (e.g., a nitride of Ti, Mo, W, Cu, Al, Ta, Ru, Ir, Co or the like.) As an example, the first and second back gate capping patterns BGC1 and BGC2 may include an insulating material. In an example, the back gate insulating pattern BGI may include at least one of silicon oxide or a high dielectric material.

An interlayer insulating film ILD may be provided on the lower insulating film LIL. The interlayer insulating film ILD may be interposed between the semiconductor patterns SP adjacent to each other in the second direction D2. As an example, the interlayer insulating film ILD may include an insulating material. The interlayer insulating film ILD may include the same material as the gate insulating pattern GI.

A connection structure CNS may be provided on a second edge portion EA2 of the semiconductor pattern SP. The connection structure CNS may be connected to the bit line BL through the semiconductor pattern SP. A plurality of the connection structures CNS may be provided. The connection structures CNS may be spaced apart from each other in the first direction D1 and the second direction D2. In a plan view, the connection structures CNS may be arranged to form a plurality of rows and columns. It may have the form of a matrix, but is not limited thereto. In a plan view, the connection structures CNS may be arranged in various shapes, such as a zigzag shape, a honeycomb shape or the like.

The connection structure CNS may include a storage node contact BC, an intervening layer SL, and a landing pad LP, which are sequentially provided on the second edge portion EA2 of the semiconductor pattern SP. The connection structure CNS may include a protection pattern PL in contact with sidewalls of the storage node contact BC, the intervening layer SL, and the landing pad LP. The storage node contact BC, the intervening layer SL, and the landing pad LP may vertically overlap each other. In some implementations, the sidewall of the storage node contact BC, the sidewall of the intervening layer SL, and the sidewall portion of the landing pad LP may be aligned. The sidewall of the landing pad LP may include a portion facing a support pattern AC and a portion facing an air gap AG.

A wall recess CRS may be defined by the landing pad LP, the intervening layer SL, and an upper portion of the storage node contact BC, and the protection pattern PL may be provided in the wall recess CRS. One sidewall of the protection pattern PL may be in contact with the landing pad LP, the intervening layer SL, and the storage node contact BC. A bottom surface of the protection pattern PL may be in contact with the storage node contact BC. The other sidewall of the protection pattern PL and an exposed sidewall of the storage node contact BC may be aligned. The other sidewall of the protection pattern PL may be exposed to the air gap AG. The bottom surface of the protection pattern PL may be at a higher level than the bottom surface of the storage node contact BC. In the present disclosure, the expression that an element is at a higher level than another element may be understood to mean that the element is located at a greater distance from the top surface of the substrate 100 in the third direction D3 than the other element. In other words, when the element is at a higher level than the other element, the distance from the top surface of the substrate 100 of the element in the third direction D3 may be greater than the distance from the top surface of the substrate of the other element in the third directions D3.

Since the bottom surface of the protection pattern PL is provided at a higher level than the bottommost surface of the storage node contact BC, at least a portion of sidewall of the storage node contact BC may be exposed. The sidewall of the storage node contact BC covered with the protection pattern PL may be protected from corrosion. Electrical signals from the semiconductor pattern SP may be better received through the exposed sidewall of the storage node contact BC without being covered by the protection pattern PL. The protection pattern PL may include silicon nitride.

The storage node contact BC may include an upper portion having a first horizontal width Wa1 and a lower portion having a second horizontal width Wa2. The second horizontal width Wa2 may be greater than the first horizontal width Wa1. At least a portion of the lower portion may vertically overlap the protection pattern PL.

The storage node contact BC and the landing pad LP may include a conductive material. The intervening layer SL may include a silicide. The protection pattern PL may include silicon nitride. As an example, each of the storage node contact BC and the landing pad LP may include at least one of a doped semiconductor material (e.g., doped silicon, doped germanium, etc.), a metal material (e. g., Ti, Mo, W, Cu, Al, Ta, Ru, Ir, Co, or the like.), metal silicide (e.g., silicide of Ti, Mo, W, Cu, Al, Ta, Ru, Ir, Co, or the like), or a metal nitride (e.g., nitride of Ti, Mo, W, Cu, Al, Ta, Ru, Ir, Co or the like). As an example, the intervening layer SL may include silicon and a metal. As an example, the protection pattern PL may include an insulating material (e.g., SiN, SiOCN, SICN, SiBN, or the like).

When the storage node contact BC includes doped silicon, a doping concentration of the storage node contact BC may decrease with increasing distance from the landing pad LP. As an example, a portion of the storage node contact BC adjacent to the exposed sidewalls of the storage node contact BC (or a portion of the storage node contact BC adjacent to the bottom surface of the storage node contact BC) may include substantially undoped polysilicon. In the present disclosure, the term “substantially” may be understood to include a deviation within 5%.

The intervening layer SL may reduce electrical contact resistance between the storage node contact BC and the landing pad LP and may improve electrical connection therebetween, and may increase reliability.

The intervening layer SL may be omitted. In this case, the storage node contact BC and the landing pad LP may be directly connected with each other.

An intervening hole CHL may be defined between the connection structures CNS. The first back gate capping pattern BGC1 and the back gate insulating pattern BGI may be recessed to a depth by the intervening hole CHL. An upper portion of each of the word line WL and the cutting pattern CT may be recessed to a depth by the intervening hole CHL. The intervening hole CHL may have a lower intervening hole BRS including a curved portion and a sidewall intervening hole WBS extending from the lower intervening holes BRS in the third direction D3.

The lower intervening hole BRS may be defined by a top surface of the word line WL or a top surface of a back gate structure BGS. The lower intervening hole BRS may have a convex shape. The lower intervening hole BRS may have a recessed portion toward the word line WL or the back gate structure BGS. The lower intervening hole BRS may have a rounded surface. The bottom surface of the lower intervening hole BRS may be, for example, a curved surface.

The sidewall intervening holes WBS may be defined between the connection structures CNS. The sidewall intervening hole WBS may be defined by the sidewall of the protection pattern PL, and the exposed sidewall of the storage node contact BC. The support pattern AC may be disposed on an upper portion of the sidewall intervening hole WBS. The support pattern AC may be spaced apart from the landing pad LP in the first direction D1.

The support pattern AC may cover a portion of an upper sidewall of the connection structures CNS. Specifically, the support pattern AC may be interposed between the adjacent connection structures CNS, and may be disposed adjacent to the landing pad LP in the first direction D1. The support pattern AC may be in contact with the protection pattern PL.

The support pattern AC may surround and cover a side surface of an upper portion of each connection structures CNS. As an example, the top surface of the support pattern AC may be substantially coplanar with a top surface of the connection structure CNS (i.e., a top surface of the landing pad LP). As an example, the support pattern AC may include an insulating material (e.g., SiN, SiOC, SiOCN, SiCN, SiBN, or the like). The support pattern AC may be spaced apart from the landing pad LP with the protection pattern PL therebetween.

Referring to FIG. 5A, the connection structure CNS may include first to fourth connection structures CNS1, CNS2, CNS3, and CNS4. The first and the second connection structures CNS1, and CNS2 may be spaced apart from each other in the first direction D1. The second connection structure CNS2 may be spaced apart from the third connection structure CNS3 in the second direction D2. The third connection structure CNS3 may be spaced apart from the fourth connection structure CNS4 in the first direction D1. The first connection structure CNS1 may be spaced apart from the third connection structure CNS3 in a fourth direction D4. The fourth direction D4 is a direction parallel to the top surface of the substrate 100 and intersects the first direction D1 and the second direction D2. The first to fourth connection structures CNS1, CNS2, CNS3, and CNS4 may be provided clockwise.

The air gap AG may be provided on a side surface of the connection structure CNS. In the present disclosure, the air gap AG may mean any region defined by a boundary of a solid and filled with a gaseous substance. As another example, the air gap AG may mean an empty space. The air gap AG may be defined by the protection pattern PL, the support pattern AC, the storage node contact BC, and the word line WL or the back gate structure BGS. The air gap AG may be defined by the intervening hole CHL. As an example, the dielectric constant of the air gap AG may be 1.

The air gap AG may include a first portion AG1 and a second portion AG2 below the first portion AG1. The first portion AG1 of the air gap AG may be provided between the connection structures CNS. The second portion AG2 of the air gap AG may be provided between the semiconductor patterns SP.

The air gap AG may extend in the third direction D3 along the side surface of the connection structure CNS. The air gap AG may extend to an upper portion of the word line WL or an upper portion of the back gate structure BGS. As an example, a width of the air gap AG may be substantially constant along the side surface of the connection structure CNS, and may be larger at the upper portion of the word line WL or the back gate structure BGS.

The first portion AG1 of the air gap AG may have a first planar area. The second portion AG2 of the air gap AG may have a second planar area. The planar area of the air gap AG may be defined, for example, as a two-dimensional area occupied by the air gap in a plan view. For example, the first planar area in the plan view of FIGS. 5A, 5B, and 5C may be an area between a plurality of connection structures CNS. For example, the first planar area may be a planar area of the air gap AG at a first vertical level LV1, a second vertical level LV2, or a third vertical level LV3 of FIG. 6A. For example, the second planar area may be a planar area of the air gap AG at a lower vertical level than a bottom surface of the plurality of connection structures CNS. In some implementations, a maximum area of the first planar area may be smaller than that of the second planar area. In some implementations, at a vertical level lower than the bottom surface of the plurality of connection structures CNS, the second planar area may increase as it approaches the top surface of the substrate 100 (see FIG. 2), reach a maximum value, and then decrease again after having the maximum value.

In the cross-sectional views of FIGS. 6A, 6B, 6C, and 6D, the first portion AG1 of the air gap AG may have a constant width. The second portion AG2 of the air gap AG may have a convex shape toward the semiconductor pattern SP. A width of the second portion AG2 of the air gap AG may increase and then decrease toward the semiconductor pattern SP. The second portion AG2 of the air gap AG may include a portion that vertically overlaps the connection structure CNS.

The air gap AG may be provided in the intervening hole CHL. The first portion AG1 of the air gap AG may be provided in the sidewall intervening hole WBS. The second portion AG2 of the air gap AG may be provided in the lower intervening hole BRS. The first portion AG1 of the air gap AG may surround the side surface of each of the connection structures CNS.

The air gap AG may be provided below the support pattern AC. The air gap AG may be provided between the support pattern AC and the word line WL, and between the support pattern AC and the back gate structure BGS.

The air gap AG may be connected to a bottom surface of the support pattern AC. The air gap AG may be connected to a side surface of the protection pattern PL and a side surface of the storage node contact BC.

The side surface of the protection pattern PL and the side surface of the storage node contact BC may be exposed by the air gap AG. In the present specification, the exposure of a certain surface by the air gap AG may mean that the certain surface is exposed by the air gap AG, so that the certain surface is not in contact with or covered by any solid element. The bottom surface of the support pattern AC may be exposed by the air gap AG. The upper portion of the word line WL may be exposed by the air gap AG. The upper portion of the back gate structure BGS may be exposed by the air gap AG.

The air gap AG may be interposed between the connection structures CNS. Accordingly, a capacitance unnecessarily formed between adjacent connection structures CNS may be reduced, rather than completely filling the space (or the gap) between the connection structures CNS with an insulating material. As a result, a disturbance by adjacent connection structures CNS may be reduced. Accordingly, the electrical characteristics of the semiconductor device can be improved.

In some implementations, since the air gap AG is interposed between the connection structures CNS, a separation distance between the connection structures CNS may be smaller than that between the connection structures CNS completely filled with an insulating material. Accordingly, the width of the connection structure CNS may be formed wider, and a contact area between the connection structure CNS and the semiconductor pattern SP may be increased. As a result, electrical characteristics of the semiconductor device can be improved.

In the present disclosure, the air gap AG may be formed not only between the connection structures CNS spaced apart in the second direction D2 or in the first direction D1, but also between the connection structures CNS diagonally spaced apart with each other in a plan view, so that electrical characteristics of the semiconductor device can be improved. In other words, the air gap AG may be formed not only between the first connection structure CNS1 and the second connection structure CNS2 spaced apart from each other in the first direction D1, but also between the first connection structures CNS1 and third connection structures CNS3 spaced apart from each other in the fourth direction D4. The support pattern AC may be connected to an upper portion of the air gap AG.

An intervening protection pattern IPL comprising the same material as the protection pattern PL may be provided. The intervening protection pattern IPL may be surrounded by some of the plurality of connection structures CNS, respectively. Each intervening protection pattern IPL may be spaced apart from the connection structures CNS with the support pattern AC interposed therebetween.

The intervening protection pattern IPL may be interposed in the support pattern AC between the first connection structure CNS1 and the third connection structure CNS3. The intervening protection pattern IPL may not be interposed in the support pattern AC between the first connection structure CNS1 and the second connection structure CNS2. The intervening protection pattern IPL may be disposed between the first connection structure CNS1 and the third connection structure CNS3. The first to fourth connection structures CNS1, CNS2, CNS3, and CNS4 may surround a single intervening protection pattern IPL.

When the connection structures CNS are in a honeycomb arrangement, three connection structures CNS may surround a single intervening protection pattern IPL.

In some implementations, an inner wall IWS of the support pattern AC may be in contact with the plurality of the connection structures CNS1, and an outer wall OWS of the support patterns AC may be in contact with the plurality of the intervening protection patterns IPL. For example, the intervening protection pattern IPL may fill a space defined by the outer wall OWS of the support pattern AC. In FIG. 6B, the outer wall OWS of the support pattern AC is illustrated as being in contact with the intervening protection pattern IPL, but the present disclosure is not limited thereto. For example, as a result of the intervening protection pattern IPL being formed of a material having low step coverage, only a portion of the space defined by the outer wall OWS of the support pattern AC may be filled.

Referring again to FIGS. 4, 5A-5C, and 6A-6C, a data storage pattern DSP may be provided on the connection structure CNS. The data storage pattern DSP may be connected to the semiconductor pattern SP through the connection structure CNS. A plurality of the data storage patterns DSP may be provided. The data storage patterns DSP may be spaced apart from each other in the first direction D1 and in the second direction D2. The data storage pattern DSP may correspond to the data storage element DS described with reference to FIGS. 1 to 3.

The data storage pattern DSP may be, for example, a capacitor including a lower electrode, a dielectric film, and an upper electrode. In this case, the semiconductor device according to the present disclosure may be a dynamic random access memory (DRAM). The data storage pattern DSP may include, for another example, a magnetic tunnel junction pattern. In this case, the semiconductor device according to the present disclosure may be a magnetic random access memory (MRAM). The data storage pattern DSP may further include a phase change material or a variable resistance material. In this case, the semiconductor device according to the present disclosure may be a phase-change random access memory (PRAM) or a resistive random access memory (ReRAM). However, this is merely illustrative and the present disclosure is not limited thereto, and the data storage pattern DSP may include various structures and/or materials capable of storing data.

Referring again to FIG. 6D, the connection structure CNS and the word line WL are shown in more detail.

The storage node contact BC of the connection structure CNS may include a first contact sidewall BSW1 exposed to the air gap AG, a second contact sidewall BSW2 in contact with the protection pattern PL, a contact bottom surface BCBS in contact with a corresponding semiconductor pattern SP among the plurality of semiconductor patterns SP, and a contact curved surface BCS between the contact bottom surface BCBS and the first contact sidewall BSW2.

The protection pattern PL may include a portion that vertically overlaps the storage node contact BC on the second contact sidewall BSW2. The contact curved surface BCS may be curved. The contact curved surface BCS may include a convex surface toward the air gap AG. The first contact sidewall BSW1, the contact curved surface BCS, and the contact bottom surface BCBS may be continuous. The contact bottom surface BCBS may be in contact with the word line WL. The contact bottom surface BCBS may be in contact with the corresponding semiconductor pattern SP among the plurality of semiconductor patterns SP, the gate insulating pattern GI, the back gate insulating pattern BGI, and the upper gate capping pattern GC1.

The protection pattern PL may include an inner wall PLW1 in contact with the storage node contact BC and the landing pad LP and an outer wall PLW0 exposed to the air gap AG. The inner wall PLW1 of the protection pattern PL and the second contact sidewall BSW2 of the storage node contact BC may include the same surface. The outer wall PLW0 of the protection pattern PL may be substantially coplanar with the first contact sidewall BSW1 of the storage node contact BC.

The sidewall intervening hole WBS of the intervening hole CHL may be defined between the first contact sidewalls BSW1 spaced apart from each other. The lower intervening hole BRS may be defined by the contact curved surface BCS and an exposed top surface of the word line WL. The lower intervening hole BRS may be defined by the top surface of the word line WL exposed by the air gap AG and the contact curved surface BCS exposed by the air gap AG.

A maximum width W1 of the lower intervening hole BRS may be defined as a maximum distance in the first direction D1. A maximum width W2 of the word line WL may be defined as a maximum distance in the first direction D1. A maximum width W3 of the sidewall intervening hole WBS may be defined as a maximum distance in the first direction D1.

The lower intervening hole BRS may have a shape convexly recessed in the word line WL. The maximum width W1 of the lower intervening hole BRS may be greater than the maximum width W3 of the sidewall intervening hole WBS. The maximum width W2 of the word line WL may be greater than the maximum width W1 of the lower intervening hole BRS.

In the present disclosure, the air gap AG may be formed between the connection structures CNS, and at the same time, the support pattern AC may be disposed between the connection structures CNS and be disposed on a top portion of the air gap AG. This can prevent warpage between the connection structures CNS and firmly support the semiconductor device, thereby improving durability.

In the present disclosure, the intervening hole CHL provided with the air gap AG may have a convex shape. This can eliminate the electric field peak point and reduce the gate induced drain leakage (GIDL). Electrical characteristics of the semiconductor device can be improved.

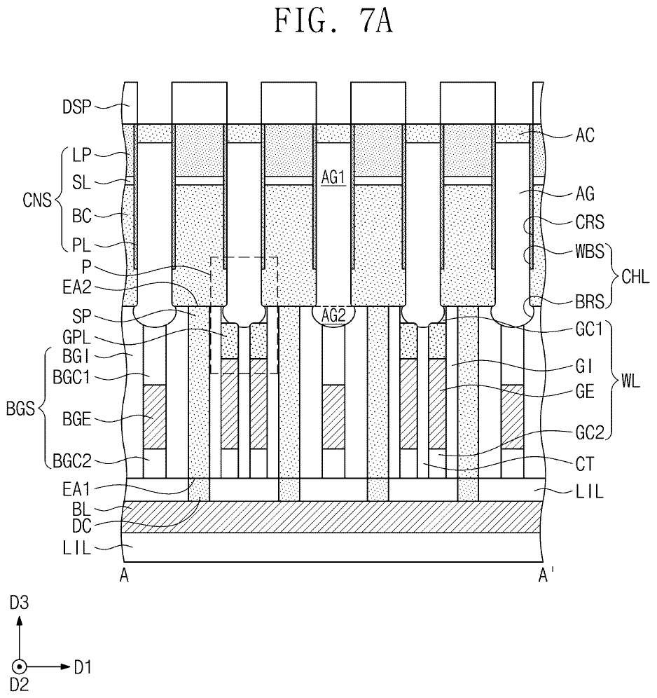

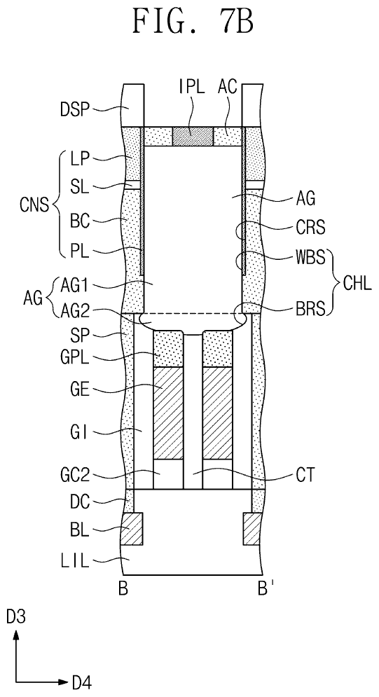

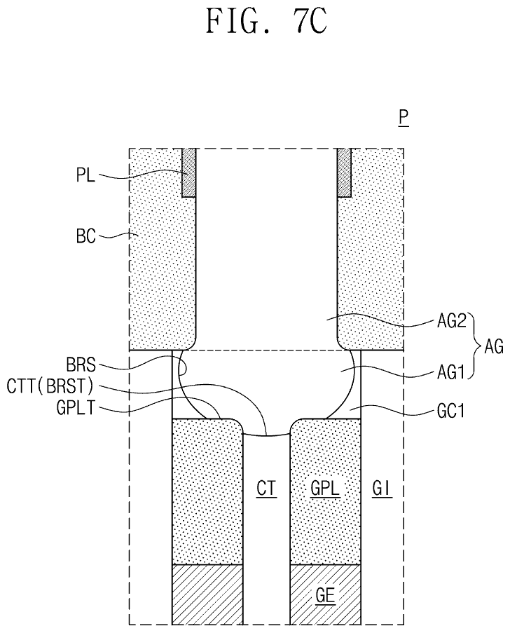

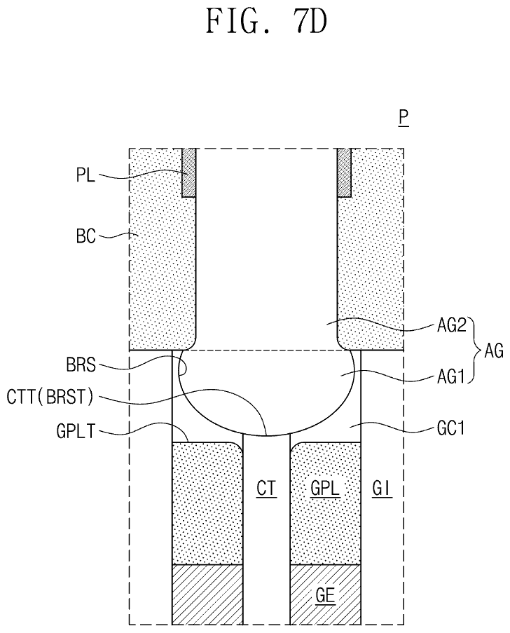

FIGS. 7A and 7B are cross-sectional views corresponding to lines A-A′ and B-B′ of FIG. 4, respectively, according to some implementations of the present disclosure. FIG. 7C is an enlarged view corresponding to P of FIG. 7A according to some implementations of the present disclosure. FIG. 7D is an enlarged view corresponding to P of FIG. 7A according to some implementations of the present disclosure. For simplicity of description, redundant explanations are omitted.

Referring to FIGS. 7A and 7B, the word line WL may include a gate electrode GE extending along the second direction D2 and the third direction D3, a gate protection pattern GPL on a top surface of the gate electrode GE, an upper gate capping pattern GC1 on the gate protection pattern GPL, and a lower gate capping pattern GC2 under a bottom surface of the gate electrodes GE.

The gate protection pattern GPL may include nitride. The gate protection pattern GPL may include, for example, silicon nitride. The lower gate capping pattern GC2 may include an oxide. The lower gate capping pattern GC2 may include, for example, silicon oxide.

An upper portion of the gate protection pattern GPL may be exposed to the air gap AG. The upper portion of the gate protection pattern GPL may have a shape protruding further toward the air gap AG than the cutting pattern CT.

The dielectric constant of the silicon nitride may be higher than that of the silicon oxide. Since the gate protection pattern GPL disposed on the top surface of the gate electrode GE has a high dielectric constant, a current boosting can occur and a current can be better transmitted.

Referring to FIG. 7C, the gate protection pattern GPL according to some implementations is shown in more detail.

A part of a top surface GPLT of the gate protection pattern GPL may be exposed to the air gap AG, and another part of the top surfaces GPLT of gate protection patterns GPL may be in contact with the upper gate capping pattern GC1.

One sidewall of the gate protection pattern GPL may be in contact with the cutting pattern CT, and the other sidewall of the gate protection pattern GPL may be in contact with the gate insulating pattern GI. A level of the top surface GPLT of the gate protection pattern GPL may be higher than that of a top surfaces CTT of the cutting patterns CT. The level of the top surface GPLT of the gate protection pattern GPL may be higher than that of the uppermost surface of the cutting pattern CT. The top surface CTT of the cutting pattern CT may include the same surface as a bottom surface BRST of the lower intervening hole BRS.

Referring to FIG. 7D, a gate protection pattern GPL according to some implementations is shown in more detail.

The top surface GPLT of the gate protection pattern GPL may be in contact with the upper gate capping pattern GC1. The top surface GPLT of the gate protection pattern GPL may be unexposed to the air gap AG. The top surface CTT of the cutting pattern CT and the top surface of the upper gate capping pattern GC1 may define a lower intervening hole BRS. The top surface CTT of the cutting pattern CT and the top surface of the upper gate capping pattern GC1 may be exposed to the air gap AG. The top surface CTT of the cutting pattern CT and the top surface of the upper gate capping pattern GC1 may be in contact with the bottom surface BRST of the lower intervening hole BRS.

One sidewall of the gate protection pattern GPL may be in contact with the cutting pattern CT, and the other sidewall of the gate protection pattern GPL may be in contact with the gate insulating pattern GI. The level of the top surface GPLT of the gate protection pattern GPL may be lower than that of the top surface CTT of the cutting pattern CT. The level of the top surface GPLT of the gate protection pattern GPL may be lower than that of the bottommost surface of the cutting pattern CT. The top surface CTT of the cutting pattern CT may include the same surface as the bottom surface BRST of the lower intervening hole BRS.

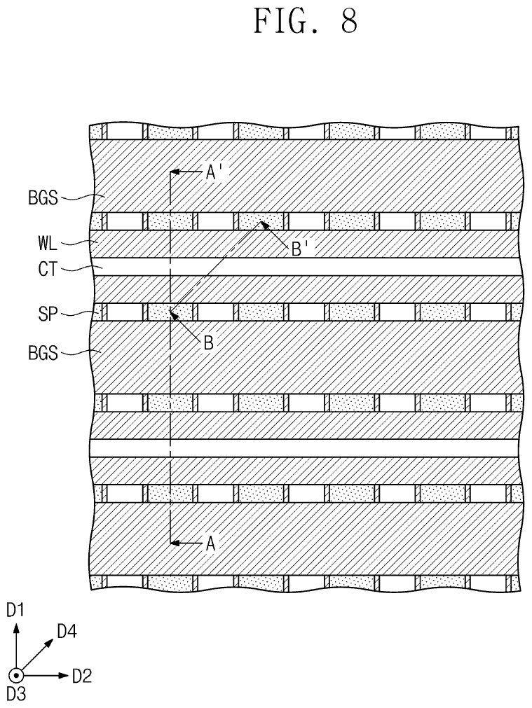

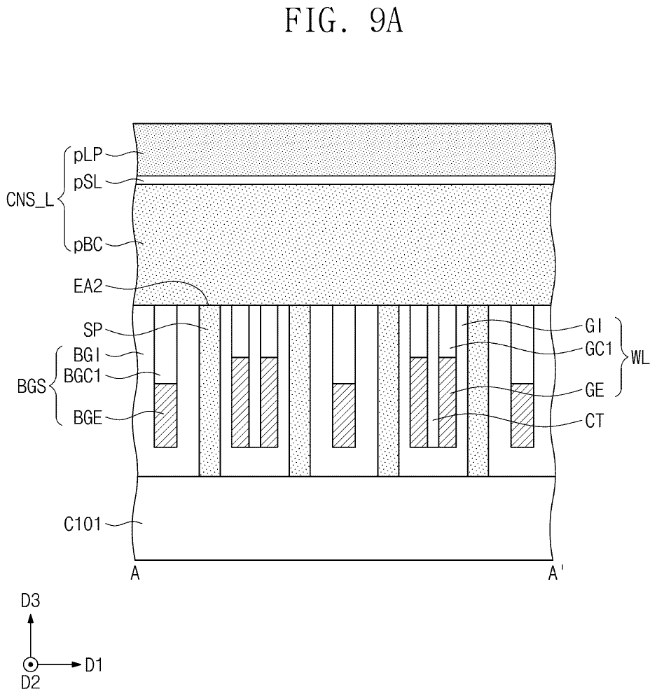

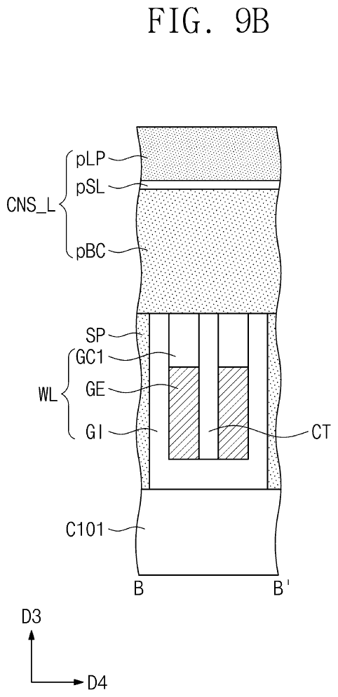

FIGS. 8 to 17B are drawings illustrating a method of manufacturing a semiconductor device according to some implementations of the present disclosure. In detail, FIGS. 8, 10, and 13 are each a plan view for describing a method of manufacturing a semiconductor device according to some implementations of the present disclosure. FIGS. 9A, 11A, 12A, 14A, 15A, 16A, and 17A are cross-sectional views respectively corresponding to line A-A′ in FIG. 4. FIGS. 9B, 11B, 12B, 14B, 15B, 16B, and 17B are cross-sectional views respectively corresponding to line B-B′ in FIG. 4.

Referring to FIGS. 8, 9A, and 9B, a manufacturing substrate C101 may be prepared. The manufacturing substrate C101 may be a carrier substrate. A semiconductor pattern SP, a back gate insulating pattern BGI, and a gate insulating pattern GI may be formed on the manufacturing substrate C101. A top surface of the manufacturing substrate C101 may be in contact with the semiconductor pattern SP, the back gate insulating pattern BGI, and the gate insulating pattern GI.

A back gate electrode BGE may be formed on the back gate insulating pattern BGI. A first back gate capping pattern BGC1 may be formed on the back gate insulating pattern BGI. A back gate structure BGS may be formed.

A gate electrode GE may be formed on the gate insulating pattern GI. An upper gate capping pattern GC1 may be formed on the gate insulating pattern GI. A cutting pattern CT may be formed between the gate electrodes GE spaced apart from each other and the upper gate capping patterns GC1. The gate insulating pattern GI may surround a pair of gate electrodes GE and upper gate capping patterns GC1, and the cutting pattern CT therebetween. A word line WL may be formed.

A preliminary contact layer pBC may be formed on the word line WL, the back gate structure BGS, and the semiconductor pattern SP. A preliminary intervening layer pSL may be formed on the preliminary contact layer pBC. A preliminary landing pad pLP may be formed on the preliminary intervening layer pSL.

The preliminary contact layer pBC may include undoped polysilicon and doped polysilicon. As an example, the concentration of doped polysilicon in the preliminary contact layer pBC may increase as its distance from the manufacturing substrate C101 increases in the third direction D3.

By forming the preliminary contact layer pBC, the preliminary intervening layer pSL, and the preliminary landing pad pLP, the preliminary connection stack CNS_L may be formed.

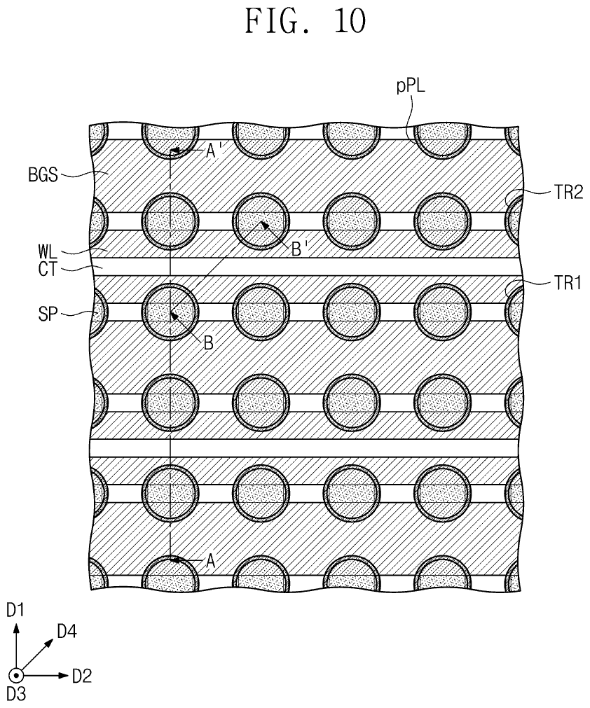

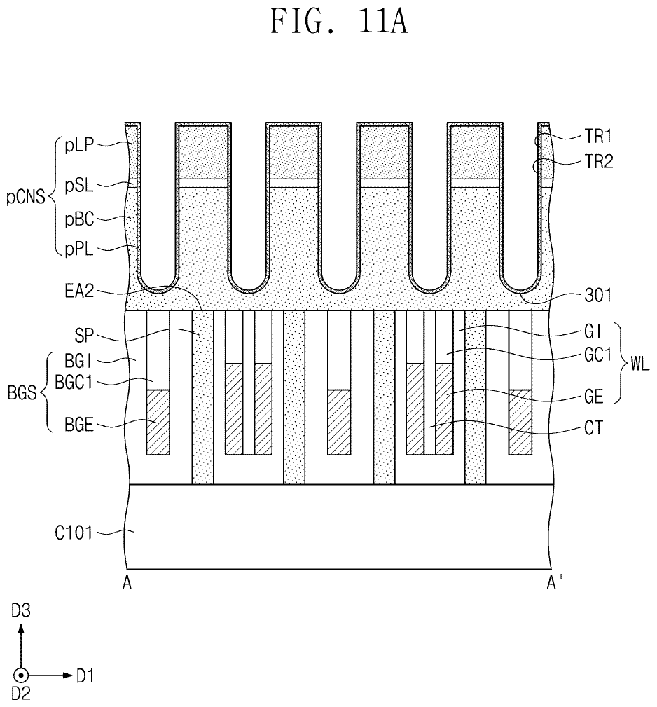

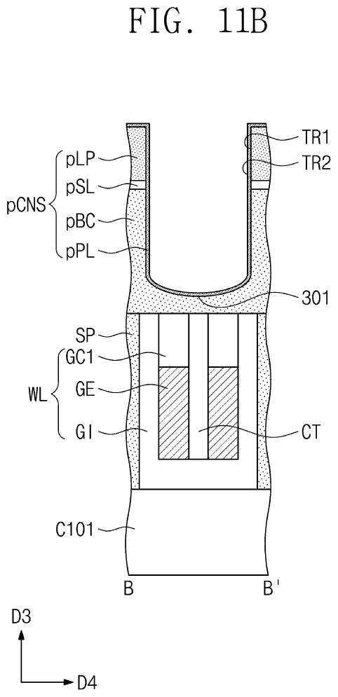

Referring to FIGS. 10, 11A, and 11B, a part of the preliminary connection stack CNS_L may be removed. Removing the part of the preliminary connection stack CNS_L may include removing a part of the preliminary connection stack CNS_L that is non-overlapping with the semiconductor pattern SP through a first patterning process. Removing the part of the preliminary connection stack CNS_L may include performing a first etching process from the preliminary connection stack CNS_L to remove a part of the preliminary connection stack CNS_L up to a level higher than a bottom surface of the preliminary connection stack CNS_L.

A first trench TR1 may be formed by removing the part of the preliminary connection stack CNS_L. In other words, the first trench TR1 may be formed through the first patterning process and the first etching process. The first trench TR1 may be defined by a sidewall of a preliminary landing pad pLP exposed through the first patterning and the first etching process, a sidewall of an exposed preliminary intervening layer pSL, and an exposed preliminary contact layer pBC.

The level of the lowest point 301 of the first trench TR1 may be higher than that of the top surface of the word line WL. A part of the preliminary connection stack CNS_L may be removed up to the lowest point 301 of the first trench TR1. The lowest point 301 of the first trench TR1 may be spaced apart from the top surface of the word line WL. The lowest point 301 of the first trench TR1 may be spaced apart from a top surface of the back gate structure BGS.

After the first trench TR1 is formed, a preliminary protective film pPL may be formed to conformally cover the first trench TR1. The preliminary protective film pPL may be formed to cover the sidewall and a top surface of the preliminary landing pad pLP, the sidewall of the preliminary intervening layer pSL, and the preliminary contact layer pBC exposed by the first trench TR1.

The preliminary protective film pPL may be formed not to fill all of the first trench TR1, but to fill only a part of the first trench TR1. The preliminary protective film pPL is formed along the first trench TR1, so that the second trench TR2 may be formed. The second trench TR2 may be defined as a top surface of the preliminary protective film pPL and a part of the first trench TR1 that is not filled with the preliminary protective film pPL.

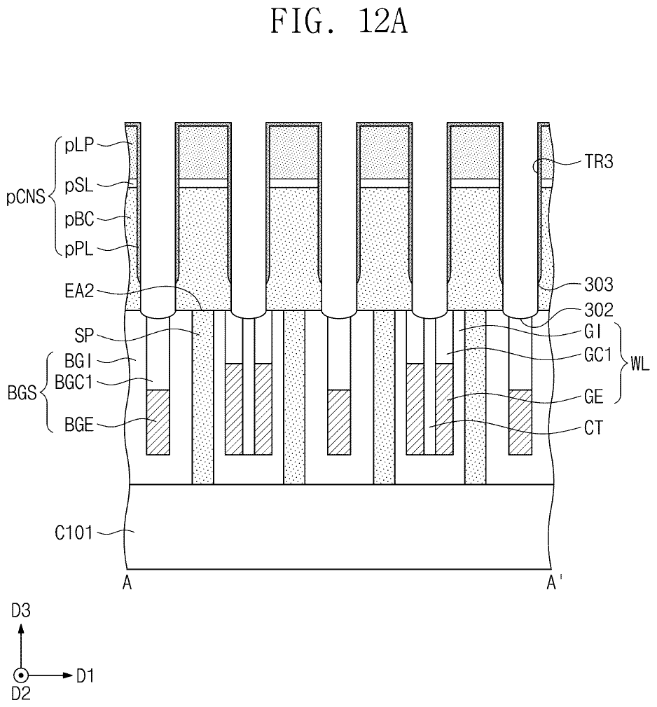

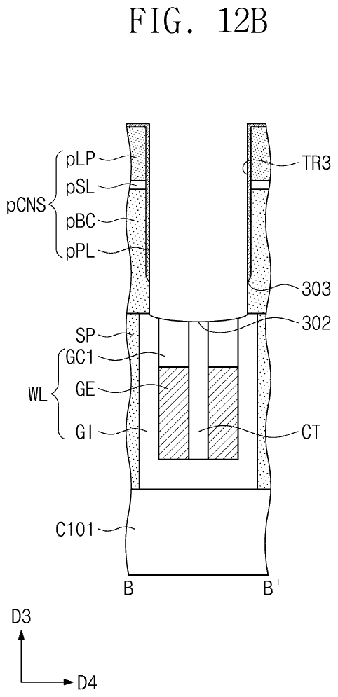

Referring to FIGS. 12A and 12B, a part of the preliminary connection stack CNS_L, a part of the preliminary protective film pPL, and a part of the word line WL may be removed. A third trench TR3 may be formed. The third trench TR3 may be defined as an exposed sidewall of the preliminary protective film pPL, an exposed sidewalls of the preliminary contact layer pBC, and an exposed top surface of the word line WL.

Removing the part of the preliminary connection stack CNS_L, the part of the preliminary protective film pPL, and the part of the word line WL may include performing a second etching process from the top surface of the preliminary connection stack CNS_L such that a part of the word lines WL is exposed. Accordingly, a lower part of the preliminary protective film pPL may be removed, and the preliminary protective film pPL may be in contact with only a part of the sidewall of the third trench TR3. The exposed sidewall of the preliminary protective film pPL and the exposed sidewall of a preliminary contact layer pBC may be substantially coplanar.

The second etching process may be performed up to a lowest point 302 of the third trench TR3. The lowest point 302 of the third trench TR3 may be defined inside the cutting pattern CT or inside the first back gate capping pattern BGC1. A level of the lowest point 302 of the third trench TR3 may be lower than that of the top surface of the word line WL. The level of the lowest point 302 of the third trench TR3 may be lower than that of the top surface of the upper gate capping patterns GC1. The level of the lowest point 302 of the third trench TR3 may be higher than a level of the top surface of the gate electrode GE.

The preliminary protective film pPL conformally covering the second trench TR2 may be partially removed in the process of forming the third trench TR3. A level of the lowest point 303 of the preliminary protective film pPL defined at the lowermost part of the preliminary protective film pPL may be higher than that of a bottom surface of the preliminary contact layer pBC. The level of the lowest point 303 of the preliminary protective film pPL may be higher than that of the lowest points 302 of the third trenches TR3.

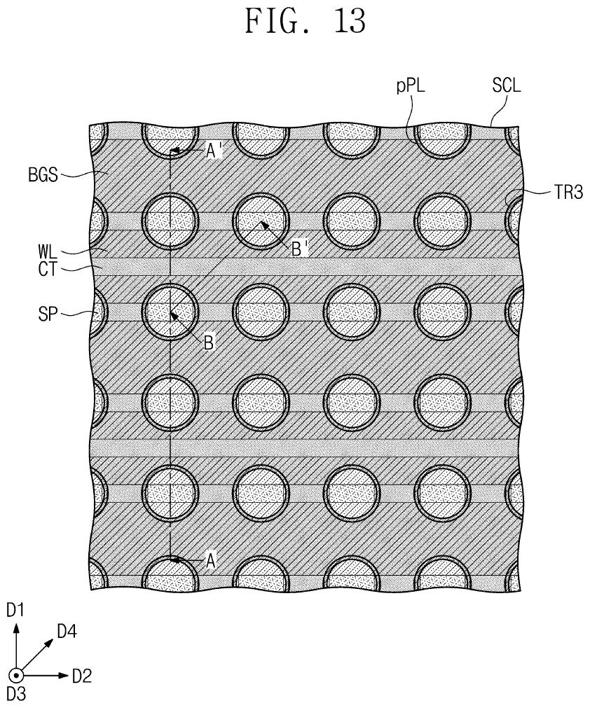

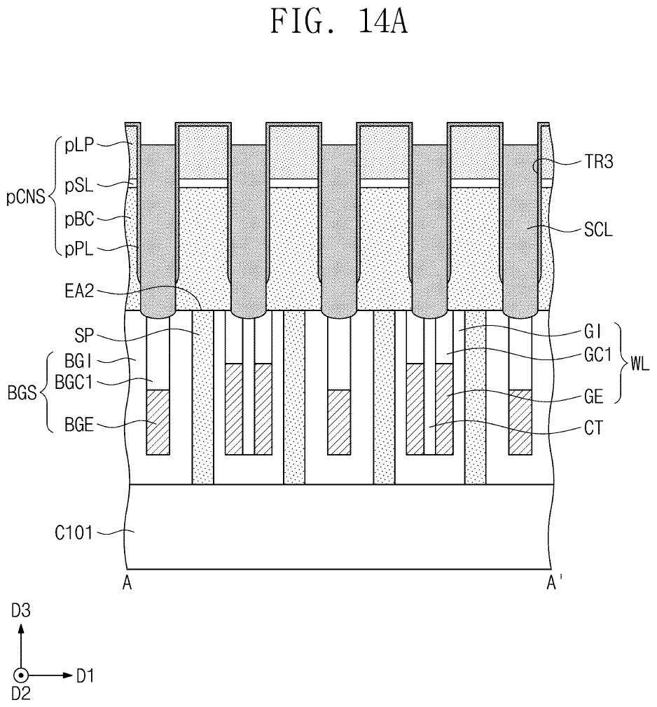

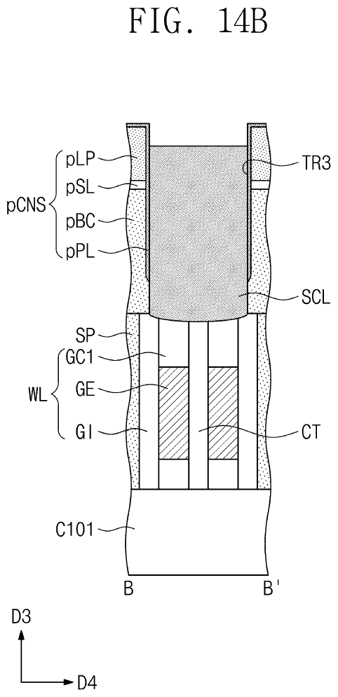

Referring to FIGS. 13, 14A, and 14B, a sacrificial layer SCL may be formed in the third trench TR3. Forming the sacrificial layer SCL may include forming the sacrificial layer SCL to fill the third trench TR3. The sacrificial layer SCL may include a material having a selectivity to the preliminary protective film pPL. The sacrificial layer SCL may include, for example, an oxide. Sidewalls of the preliminary contact layer pBC and the preliminary protective film pPL exposed by the sacrificial layer SCL may be covered. A level of a top surface of the sacrificial layer SCL may be lower than that of a top surfaces of the preliminary connection structures pCNS.

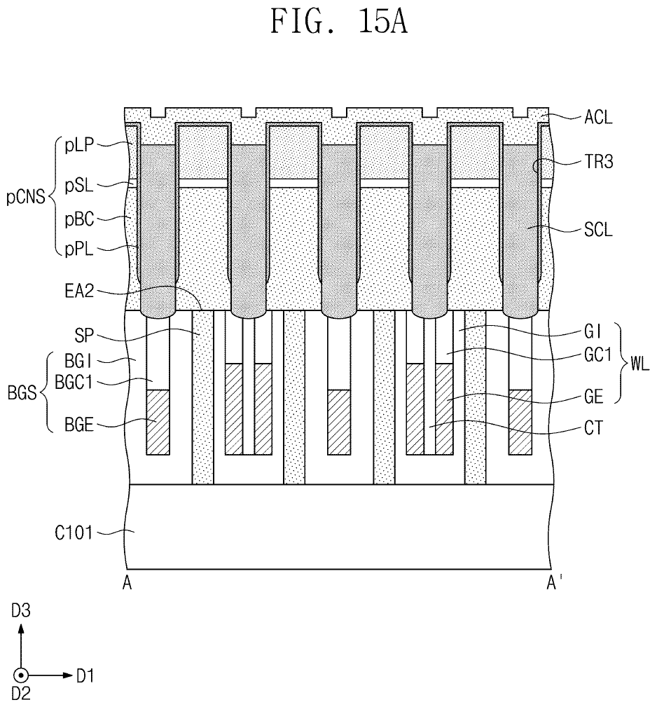

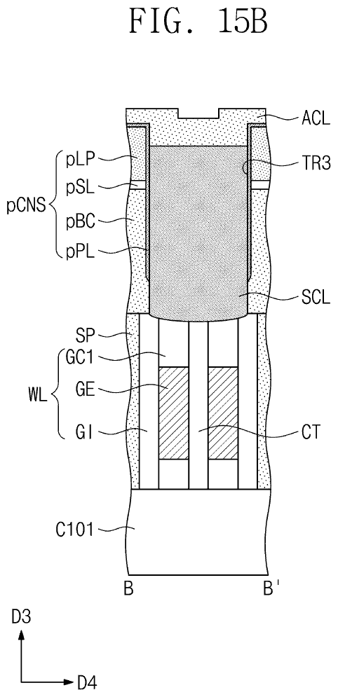

Referring to FIGS. 15A and 15B, a preliminary support layer ACL may be formed on the sacrificial layer SCL. The preliminary support layer ACL may be formed to cover the top surface of the sacrificial layer SCL, the sidewall and the top surface of the preliminary protective film pPL. Forming the preliminary support layer ACL may include, for example, atomic layer deposition (ALD) of silicon nitride.

The preliminary support layer ACL may include a material that has a selectivity to oxides and is wet resistant. The preliminary support layer ACL may include, for example, SiN or SiBN.

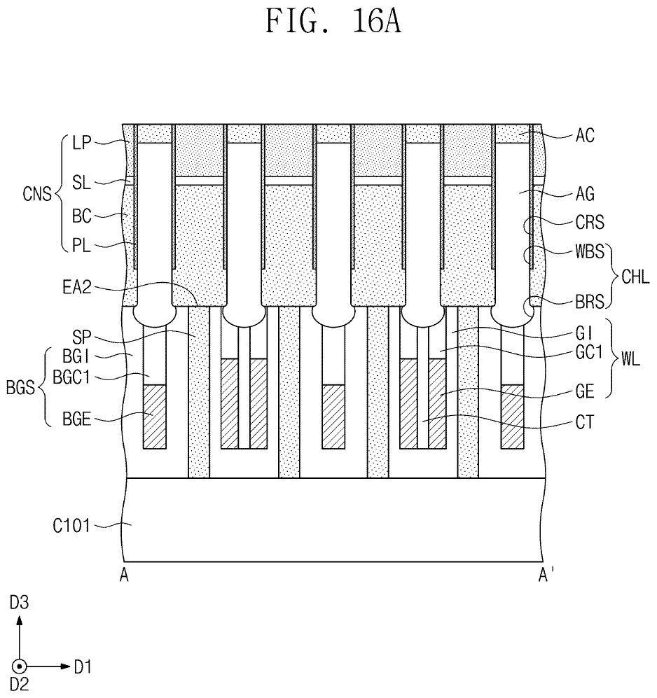

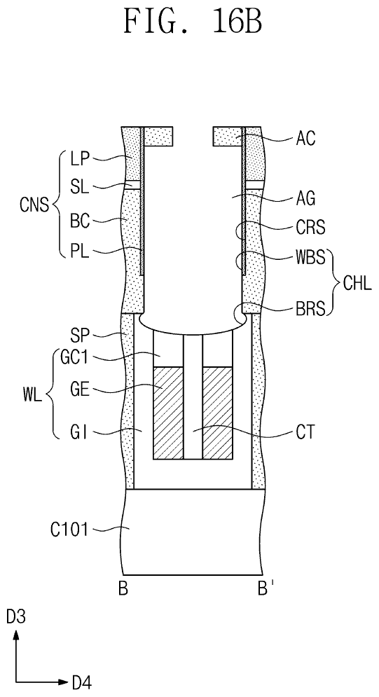

Referring to FIGS. 16A and 16B, a part of the preliminary support layer ACL may be removed to form the support pattern AC. The preliminary protective film pPL covering the preliminary landing pad pLP, and a part of an upper part of the preliminary landing pad pLP may be removed. The landing pad LP may be formed. The protection pattern PL may be formed. A top surface of the landing pad LP may be exposed. A top surface of the support pattern AC, a top surface of the protection pattern PL, and the top surface of the landing pad LP may be substantially coplanar. The top surface of the support pattern AC, the top surface of the protection pattern PL, and the top surface of the landing pad LP may be substantially coplanar by a planarization process.

The support pattern AC interposed between the plurality of connection structures CNS spaced apart in the first direction D1 may be continuous. In other words, no separate structure may be interposed inside the support pattern AC in the first direction D1, and the support patterns AC may not be spaced apart from each other.

The support pattern AC interposed between the plurality of connection structures CNS spaced apart in the fourth direction D4 may be discontinuous. In other words, each of the plurality of support patterns AC may be in contact with a corresponding one of the plurality of connection structures CNS, and the plurality of support pattern AC may be spaced apart from each other in the fourth direction D4. For example, after the part of the preliminary support layer ACL is removed, the support patterns AC may be spaced apart from each other through separate etching.

The sacrificial layer SCL may be removed. A region where the sacrificial layer SCL is removed may be defined as the air gap AG. Since the sacrificial layer SCL is removed after the support patterns AC are formed, warpages of the connection structures CNS may be prevented while the above processes are performed.

When the sacrificial layer SCL is removed, a portion of the word line WL may be removed together. When the sacrificial layer SCL is removed, a part of the preliminary contact layer pBC may be removed together. The part of the preliminary contact layer pBC may be removed such that a lower portion of the preliminary contact layer pBC is exposed, the upper portion of the word line WL is exposed, and the upper portion of a back gate structure BGS is exposed. In the process of removing the part of the preliminary contact layer pBC, the upper gate capping pattern GC1 and the gate insulating pattern GI of the word line WL may be additionally removed. In the process of removing the part of the preliminary contact layer pBC, the first back gate capping pattern BGC1 and the back gate insulating pattern BGI of the back gate structure BGS may be additionally removed. Removing the part of the preliminary contact layer pBC may include removing the lower portion of the preliminary contact layer pBC. Removing the lower portion of the preliminary contact layer pBC may include smoothing a portion of the preliminary contact layer pBC that is in contact with the word line.

The sacrificial layer SCL, the part of the preliminary contact layer pBC, a part of the word line WL, and a part of the back gate structure BGS may be removed to form the intervening hole CHL. By removing the part of the preliminary contact layer pBC and the part of the word line WL, the lower intervening hole BRS may be formed to have a wider width than the sidewall intervening hole WBS.

A portion of the preliminary contact layer pBC may be removed to form the storage node contact BC. The connection structure CNS may be formed.

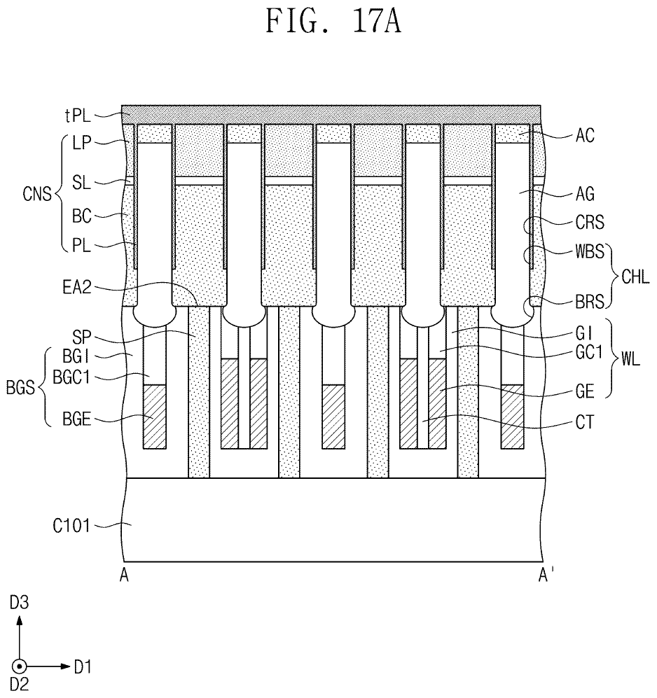

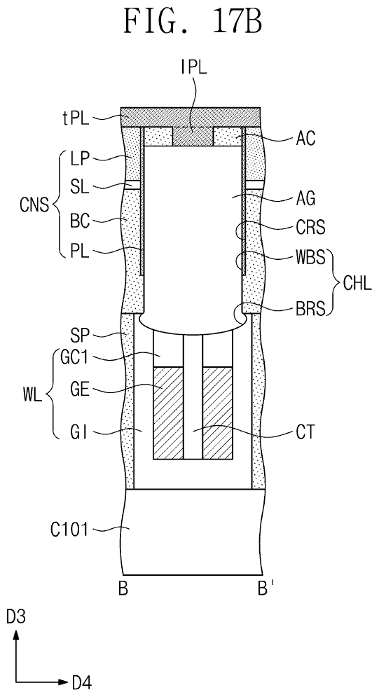

Referring to FIGS. 17A and 17B, the storage node contact BC may be removed to have a smooth connection surface with the underlying word line WL or back gate structure BGS. A lower portion of the storage node contact BC and the lower intervening hole BRS may be smoothly connected. This process may be done, for example, by a wet or dry cleaning.

An upper protection pattern tPL and an intervening protection pattern IPL may be formed on the support pattern AC and between the support patterns AC. The upper protection pattern tPL and the intervening protection pattern IPL may be formed together, and the upper protection pattern tPL may be defined at a level higher than a level of the top surface of the landing pad LP, and the intervening protection pattern IPL may be defined at a lower level than the level of a top surface of the landing pad LP.

The intervening protection pattern IPL may be formed to fill between the support patterns AC. The upper protection pattern tPL and the intervening protection pattern IPL may include a material having a low step coverage. The upper protection pattern tPL and the intervening protection pattern IPL may include nitride.

Referring again to FIGS. 4 and 6A to 6D, the manufacturing substrate C101 may be removed. A portion of the word line WL, a portion of the semiconductor pattern SP, and a portion of the back gate structure BGS in contact with the manufacturing substrate C101 may be removed through a planarization process. The back gate electrode BGE covered with the back gate insulating pattern BGI and the gate electrode GE covered with the gate insulating pattern GI may be exposed.

Then, the gate electrode GE and the back gate electrode BGE may be additionally removed, and the lower gate capping pattern GC2 and the second back gate capping pattern BGC2 may be formed.

The bit line contact DC may be formed on the semiconductor pattern SP. The bit line BL may be formed on the bit line contact DC. The lower insulating film LIL may be formed to cover the bit line contact DC and the bit line BL. The lower insulating film LIL may be formed at various times regardless of before and after formation of the bit line contact DC and the bit line BL.

The upper protection pattern tPL may be removed. Removing the upper protection pattern tPL may comprise planarization through a planarization process so that the top surface of the support pattern AC, the top surface of the landing pad LP, and the top surface of a protection pattern PL are substantially coplanar. The data storage pattern DSP may be formed on the landing pad LP. The semiconductor device of FIGS. 4, 6A-6D may be formed.

According to the inventive concept, an air gap and a support pattern may be interposed between the connection structures. The presence of an air gap may reduce the unnecessarily capacitance between landing pads and storage node contacts, rather than filling them with insulating material. As a result, a disturbance by adjacent connection structures can be reduced. At the same time, the connection structure can be supported more firmly by the support pattern. Bending of the storage node contacts can be prevented. Accordingly, electrical characteristics of the semiconductor device can be improved.

In some implementations, there may be a curved portion at the bottom of the storage node contact. The lower portion may be formed as a curved portion to be connected to the gate capping pattern, therefore the E-Field peak point is removed, and the GIDL may be reduced. As a result, electrical characteristics of the semiconductor device can be improved.

A method for manufacturing a semiconductor device according to an example implementation of the present disclosure may comprise: forming a back gate structure including a back gate insulating pattern, a back gate electrode, and a first back gate capping pattern; forming a word line including a gate insulating pattern, a gate electrode, and an upper gate capping pattern; forming a preliminary connection stack including a preliminary contact layer, a preliminary intervening layer, and a preliminary landing pad on the back gate structure and the word line; removing a portion of the preliminary connection stack to form a first trench; forming a preliminary protective film along the first trench to form a second trench; removing part of the word line, part of the preliminary protective film, and part of the preliminary contact layer to form a third trench; forming a sacrificial layer on the third trench; forming a preliminary support layer on the sacrificial layer; removing a portion of the preliminary support layer to form a support pattern; removing the sacrificial layer.

The method for manufacturing a semiconductor device according to an example implementation of the present disclosure may comprise forming an upper protection pattern and an intervening protection pattern on the support pattern after removing the sacrificial layer, and the intervening protection pattern may be interposed between mutually spaced support patterns among the support patterns.

In the method for manufacturing a semiconductor device according to an example implementation of the present disclosure, a lower portion of the preliminary contact layer may be partially removed after the removal of the sacrificial layer.

In the method for manufacturing a semiconductor device according to an example implementation of the present disclosure, the level of the lowest point of the first trench may be higher than the level of the lowermost point of the third trench.

In the method for manufacturing a semiconductor device according to an example implementation of the present disclosure, the preliminary protective film may include a material having a selectivity to the sacrificial layer.

In the method for manufacturing a semiconductor device according to an example implementation of the present disclosure, the preliminary protective film may include silicon nitride, and the sacrificial layer may include an oxide.

The method for manufacturing a semiconductor device according to an example implementation of the present disclosure may comprise removing a lower portion of a preliminary contact layer after the removal of the sacrificial layer, and the removing the lower portion of the preliminary contact layer may include smoothing a portion in the preliminary contact layer that is in contact with the word line.

While the present disclosure contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The foregoing description of implementations of the present disclosure provides an illustration for the description of the present disclosure. Therefore, the present disclosure are not limited to the above implementations, and it is obvious that various modifications and changes can be made by those skilled in the art within the technical spirit of the present disclosure, such as implementing the above implementations in combination.

What is claimed is:

1. A semiconductor device comprising:
a bit line extending in a first direction;
a word line extending in a second direction intersecting the first direction;
a plurality of semiconductor patterns on the bit line and extending in a third direction orthogonal to the first direction and the second direction and spaced apart from each other;
connection structures respectively disposed on a corresponding semiconductor pattern among the plurality of semiconductor patterns;
a support pattern between the connection structures; and
an air gap below the support pattern,
wherein each of the connection structures comprises:
a storage node contact, and
a protection pattern in contact with at least a portion of a sidewall of the storage node contact,
wherein a level of a bottom surface of the protection pattern is higher than a level of a bottommost surface of the storage node contact.

2. The semiconductor device of claim 1,
wherein the air gap includes a first portion between the connection structures and a second portion between the semiconductor patterns.

3. The semiconductor device of claim 2,
wherein the second portion of the air gap includes a portion that overlaps the connection structure in the third direction.

4. The semiconductor device of claim 1,
wherein the storage node contact includes:
a first contact side wall exposed to the air gap,
a second contact sidewall in contact with the protection pattern,
a contact bottom surface in contact with a corresponding semiconductor pattern among the plurality of semiconductor patterns, and
a contact curved surface between the contact bottom surface and the first contact sidewall.

5. The semiconductor device of claim 1, wherein:
the support pattern is in contact with sidewalls of an upper portion of the connection structures, and
the support pattern is spaced apart from a landing pad with the protection pattern interposed between the support pattern and the landing pad.

6. The semiconductor device of claim 1, comprising an intervening protection pattern comprising a same material as the protection pattern,
wherein, the connection structures comprise:
a first connection structure,
a second connection structure spaced apart from the first connection structure in the first direction, and
a third connection structure spaced apart from the second connection structure in a second direction,
wherein the first connection structure and the third connection structure are spaced apart in a fourth direction intersecting the first direction and the second direction,
wherein the intervening protection pattern is disposed between the first connection structure and the third connection structure.

7. The semiconductor device of claim 1,
wherein the word line includes:
a gate electrode extending along the second direction and the third direction,
a gate protection pattern on a top surface of the gate electrode, and
a lower gate capping pattern below a bottom surface of the gate electrode,
wherein the gate protection pattern comprises a different material than the lower gate capping pattern.

8. The semiconductor device of claim 7, wherein the word line comprises a plurality of word lines, wherein the semiconductor device comprises a cutting pattern interposed between the plurality of word lines adjacent to each other,
wherein a level of a top surface of the gate protection pattern is higher than a level of a top surface of the cutting pattern.

9. A semiconductor device, comprising:
a bit line extending in a first direction;
a word line extending in a second direction intersecting the first direction;
a plurality of semiconductor patterns on the bit line and extending in a third direction orthogonal to the first direction and the second direction and spaced apart from each other;
connection structures respectively disposed on a corresponding semiconductor pattern among the plurality of semiconductor patterns;
a support pattern between the connection structures; and
an air gap below the support pattern,
wherein each of the connection structures comprises:
a storage node contact,
a landing pad over the storage node contact, and
a protection pattern in contact with a sidewall of the landing pad and a sidewall of the storage node contact,
wherein the storage node contact includes:
a first contact side wall exposed to the air gap,
a contact bottom surface in contact with a corresponding semiconductor pattern among the plurality of semiconductor patterns, and
a contact curved surface between the contact bottom surface and the first contact side wall.

10. The semiconductor device of claim 9,
wherein the sidewall of the landing pad includes a portion facing the support pattern and a portion facing the air gap.

11. The semiconductor device of claim 9, wherein:
a level of a bottom surface of the protection pattern is higher than a level of a bottom surface of the storage node contact.

12. The semiconductor device of claim 9, comprising intervening protection patterns, wherein corresponding ones of the connection structures among the connection structures are disposed outside a periphery of each intervening protection pattern of the intervening protection patterns,
wherein each intervening protection pattern of the intervening protection patterns is spaced apart from the corresponding ones of the connection structures with the support pattern between each intervening protection pattern and the corresponding ones of the connection structures.

13. The semiconductor device of claim 9, wherein:
the air gap includes a first portion having a first planar area, and a second portion having a second planar area greater than the first planar area, and
the first portion of the air gap is located at a higher vertical level than the second portion of the air gap.

14. The semiconductor device of claim 9, wherein:
the storage node contact includes an upper portion having a first horizontal width and a lower portion having a second horizontal width that is greater than the first horizontal width, and
at least a portion of the lower portion overlaps the protection pattern in the third direction.

15. The semiconductor device of claim 9, wherein:
one sidewall of the protection pattern is exposed to an air gap, and
a bottom surface of the protection pattern is in contact with the storage node contact.

16. The semiconductor device of claim 9, wherein:
the air gap comprises a first portion between the connection structures and a second portion between the semiconductor patterns, and
the second portion of the air gap includes a portion that overlaps the protection pattern in the third direction.

17. The semiconductor device of claim 16, comprising an intervening layer between the landing pad and the storage node contact,
wherein the intervening layer comprises a silicide,
wherein a side surface of the intervening layer is in contact with the protection pattern.

18. A semiconductor device, comprising:
a substrate;
a bit line extending on the substrate in a first direction parallel to a top surface of the substrate;
a word line extending in a second direction intersecting the first direction, the word line including a gate electrode extending along a third direction orthogonal to the first direction and the second direction and a lower gate capping pattern below a bottom surface of the gate electrode;
a plurality of semiconductor patterns over the bit line and extending in the third direction and spaced apart from each other;
connection structures respectively disposed on a corresponding semiconductor pattern among the plurality of semiconductor patterns;
data storage patterns on the connection structures;
a support pattern between the connection structures; and
an air gap below the support pattern,
wherein each of the connection structures comprises:
a storage node contact,
a landing pad over the storage node contact, and
a protection pattern in contact with a sidewall of the landing pad and a sidewall of the storage node contact,
wherein a level of a bottom surface of the protection pattern is higher than a level of a bottom surface of the storage node contact.

19. The semiconductor device of claim 18, comprising a gate protection pattern on a top surface of the gate electrode,
wherein the gate protection pattern comprises silicon nitride,
wherein the lower gate capping pattern comprises an oxide.

20. The semiconductor device of claim 18,
wherein the storage node contact includes:
a first contact side wall exposed to the air gap,
a contact bottom surface in contact with a corresponding semiconductor pattern among the plurality of semiconductor patterns, and
a contact curved surface between the contact bottom surface and the first contact side wall.
